(19) United States
(12) Patent Application Publication
(10) Pub. No.: US 2016/0269021 A1
(43) Pub. Date: Sep. 15, 2016

(54) Collector-Side-Base-Driven Two-Base-Contact Bipolar Transistor with Reduced Series Resistance

(71) Applicant: Ideal Power Inc., Austin, TX (US)

(72) Inventor: Richard A. Blanchard, Los Altos, CA (US)

(21) Appl. No.: 15/018,844

(22) Filed: Feb. 8, 2016

Related U.S. Application Data
(63) Continuation of application No. 15/004,872, filed on Jan. 22, 2016.
(60) Provisional application No. 62/112,929, filed on Feb. 6, 2015.

(51) Int. Cl. H03K 17/60; H01L 29/74; H01L 29/747

(52) U.S. Cl. CPC H03K 17/60; H01L 29/747; H01L 29/7416

(57) ABSTRACT

Improved B-TRAN devices, and collector-side-base-drive methods, in which an additional doping component is added between the base contact region and the base region at the center of the die's thickness.

### CROSS-REFERENCE

Priority is claimed from U.S. application 62/112,929 (att'y docket IPC-239-P), and also from U.S. application Ser. No. 15/004,872, both of which are hereby incorporated by reference.

### BACKGROUND

The present application relates to power bipolar transistors, and more particularly to double-base-contact transistors of the type known as “B-TRAN.”

Note that the points discussed below may reflect the hindsight gained from the disclosed inventions, and are not necessarily admitted to be prior art.

Published application US 2014-0375287 (which is hereby incorporated by reference) disclosed a fully bidirectional bipolar transistor with two base terminals. Such transistors are referred to as “B-TRANs.” The base region of the transistor is preferably the bulk of a semiconductor die. The transistor preferably has two emitter/collector regions, one on each face of the die. Two distinct base contact regions are also provided—one on each face of the die. Thus, for example, with a p-type semiconductor die, each face would include an n+ emitter/collector region and a p-type base contact region. Isolation trenches and peripheral field-limiting rings are preferably also included, but in essence the B-TRAN is a four-terminal three-layer device.

An example of a B-TRAN structure is generally illustrated in FIG. 4. In this Figure, both faces of a semiconductor die carry emitter/collector regions which form a junction with the bulk substrate. Base contact regions are also present on both faces. This example shows an npn structure, so the emitter/collector regions are n-type, and the base contact regions are p-type. A shallow n+ contact doping provides ohmic contact from the separate emitter/collector terminals (on the two opposite faces of the semiconductor die, in this example) to the emitter/collector regions, and a shallow p+ contact doping provides ohmic contact from the separate base terminals (on the two opposite faces of the die) to the base contact regions. In this example, the dielectric-filled trenches provide lateral separation between the base contact regions and the emitter/collector regions. However, each trench can also include a conducting region, such as doped polysilicon, that is surrounded by a dielectric, and is electrically connected to the emitter/collector to form a vertical field plate, increasing breakdown voltage. (Note that a p-type diffused region may be added to reduce the series resistance between the emitter-to-base junction and the base contact.) B-TRANs can provide significantly better efficiency than is conventionally available for existing static transfer switches; for example, a 1200V B-TRAN has an expected system efficiency of 99.9%.

Parent application US 2014-0375287 also describes some surprising aspects of operation of this kind of device. Notably: 1) when the device is turned on, it is preferably first operated merely as a diode, and base drive is then applied to reduce the on-state voltage drop. 2) Base drive is preferably applied to the base nearest whichever emitter/collector region will be acting as the collector (as determined by the external voltage seen at the device terminals). This operation is very different from typical bipolar transistor operation, where the base contact is (typically) closely connected to the emitter-base junction but may be far from the collector contact. 3) A two-stage turnoff sequence is preferably used. In the first stage of turnoff, the transistor is brought out of full bipolar conduction, but still is connected to operate as a diode; in the final state of turnoff diode conduction is blocked too. 4) In the off state, base-emitter voltage (on each side) is limited by an external low-voltage diode which parallels that base-emitter junction. This prevents either of the base-emitter junctions from getting anywhere close to forward bias, and avoids the degradation of breakdown voltage which can occur otherwise.

Since the B-TRAN is a fully symmetric device, there is no difference between the two emitter/collector regions. However, in describing the operation of the device, the externally applied voltage will determine which side is (instantaneously) acting as the emitter, and which is acting as the collector. The two base contact terminals are accordingly referred as the “e-base” and “c-base”, where the c-base terminal is on the side of the device which happens to be the collector side at a given moment.

FIG. 3A shows a sample equivalent circuit for one exemplary NPN B-TRAN. Body diodes 312A and 312B can correspond to e.g. the upper and lower P-N junctions, respectively. Switches 314A and 314B can short respective base terminals 108A and 108B to respective emitter/collector terminals 106A and 106B.

In one sample embodiment, a B-TRAN can have six phases of operation in each direction, as follows.

1) Initially, as seen in FIG. 3B, voltage on emitter/collector terminal T1 is positive with respect to emitter/collector terminal T2. Switches 314A and 316A are open, leaving base terminal B1 open. Switch 314B is closed, shorting base terminal B2 to emitter/collector terminal T2. This, in turn, functionally bypasses body diode 312B. In this state, the device is turned off. No current will flow in this state, due to the reverse-biased P-N junction (represented by body diode 312A) at the upper side of the device.

2) As seen in FIG. 3C, the voltage on emitter/collector terminal T1 is brought negative with respect to emitter/collector terminal T2. P-N diode junction 312A is now forward biased, and now begins injecting electrons into the drift region. Current flows as for a forward-biased diode.

After a short time, e.g. a few microseconds, the drift layer is well-charged. The forward voltage drop is low, but greater in magnitude than 0.7 V (a typical silicon diode voltage drop). In one sample embodiment, a typical forward voltage drop (Vf) at a typical current density of e.g. 200 A/cm² can have a magnitude of e.g. 1.0 V.

3) To further reduce forward voltage drop Vf, the conductivity of the drift region is increased, as in e.g. FIG. 3D. To inject more charge carriers (here, holes) into the drift region, thereby increasing its conductivity and decreasing forward voltage drop Vf, base terminal B2 is disconnected from terminal T2 by opening switch 314B. Base terminal B2 is then connected to a source of positive charge by switch 316B. In one sample embodiment, the source of positive charge can be, e.g., a capacitor charged to +1.5 VDC. As a result, a surge current will flow into the drift region, thus injecting holes. This will in turn cause upper P-N diode junction 312A to inject even more electrons into the drift region. This significantly increases the conductivity of the drift region and decreases forward voltage drop Vf to e.g. 0.1-0.2 V, placing the device into saturation.

4) Continuing in the sample embodiment of FIG. 3D, current continuously flows into the drift region through base terminal B2 to maintain a low forward voltage drop Vf. The necessary current magnitude is determined by, e.g., the gain of equivalent NPN transistor 318. As the device is being driven in a high level injection regime, this gain is determined by high level recombination factors such as e.g. surface recombination velocity, rather than by low-level-regime factors such as thickness of, and carrier lifetime within, the base/drift region.

5) To turn the device off, as in e.g. FIG. 3E, base terminal B2 is disconnected from the positive power supply and connected instead to emitter terminal T2, opening switch 316B and closing switch 314B. This causes a large current to flow out of the drift region, which in turn rapidly takes the device out of saturation. Closing switch 314A connects base terminal B1 to collector terminal T1, stopping electron injection at upper P-N junction 312A. Both of these actions rapidly remove charge carriers from the drift region while only slightly increasing forward voltage drop Vf. As both base terminals are shorted to the respective emitter/collector terminals by switches 314A and 314B, body diodes 312A and 312B are both functionally bypassed.

6) Finally, at an optimum time (which can be e.g. nominally 2 μs for a 1200 V device), full turn-off can occur, as seen in e.g. FIG. 3F. Full turn-off can begin by opening switch 314B, disconnecting base terminal B2 from corresponding terminal T2. This causes a depletion region to form from lower P-N diode junction 312B as it goes into reverse bias. Any remaining charge carriers recombine, or are collected at the upper base. The device stops conducting and blocks forward voltage.

The procedure of steps 1-6 can, when modified appropriately, used to operate the device in the opposite direction. Steps 1-6 can also be modified to operate a PNP B-TRAN (e.g. by inverting all relevant polarities).

Note that, even though the B-TRAN is a four-terminal device, with two base contact regions which are operated separately, its device physics are those of a three-layer device—i.e. it only has one base region. That is the center of the die's vertical extent, between the two emitter junctions. Since the B-TRAN is a symmetrically bipolar device, only one of the two emitter/collector regions will be operating as an emitter at any given moment; but the bottom junction of either emitter/collector region is referred to here, for convenience, as an “emitter junction.”

A somewhat similar structure was shown and described in application WO2014/122472 of Wood. However, that application is primarily directed to different structures. The Wood application also does not describe the methods of operation described in the US 2014-0375287 application.

### Collector-Side-Base-Driven Two-Base-Contact Bipolar Transistor with Reduced Series Resistance

The present application teaches, among other innovations, improved B-TRAN devices and operating methods, in which additional doping is added near the base contact, to reduce the series resistance between the heavily-doped base contact region and the voltage-withstand part of the device.

The above innovations are implemented, in various disclosed embodiments, by a combination of dopant introduction steps with activation/drive steps which produces reduced resistivity in the semiconductor material above the bottom of the trench which separates each base contact location from the nearby emitter/collector region. By correct use of thermal cycles, a close approximation of symmetry is maintained between the frontside and back side structures.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 schematically shows an example of an improved B-TRAN, in which series resistance from each base contact location and the voltage-withstand region is reduced as disclosed in the present application.

FIG. 2 shows an example of a B-TRAN structure as shown in other patent applications.

FIGS. 3A-3F show successive phases of operation of a B-TRAN, as disclosed in previous patent filings of the Applicant.

FIG. 4 shows a B-TRAN which has been modified to reduce series resistance.

FIGS. 5A-5E show simulation results for various embodiments of the disclosed inventions.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

The present application discloses new device structure and fabrication sequence for a B-TRAN-type transistor.

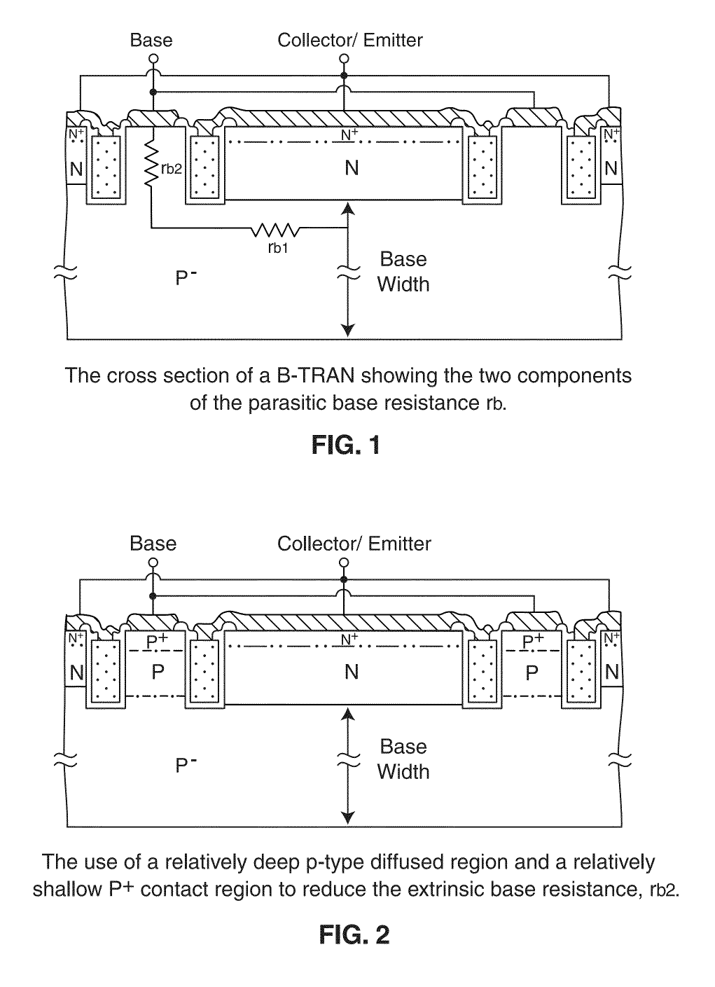

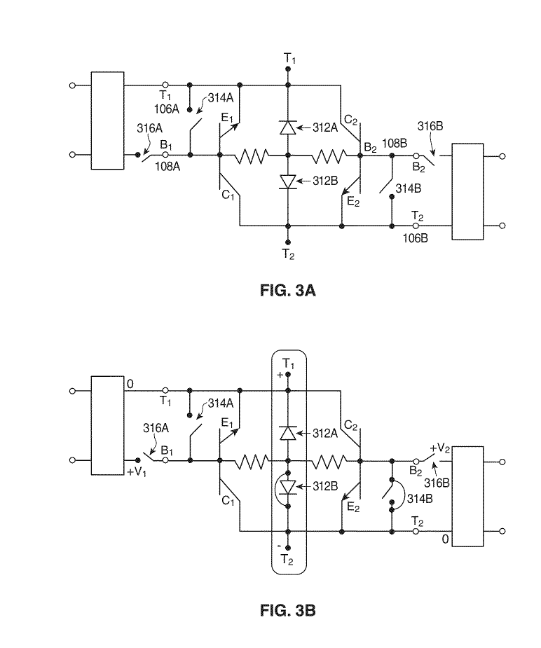

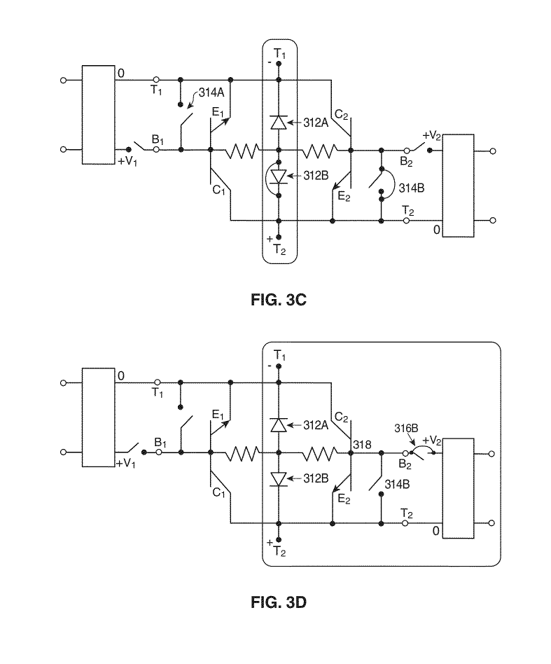

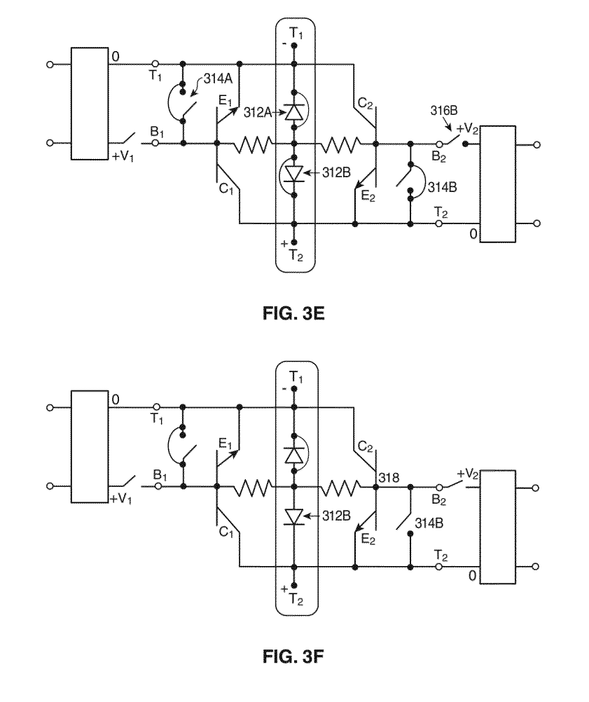

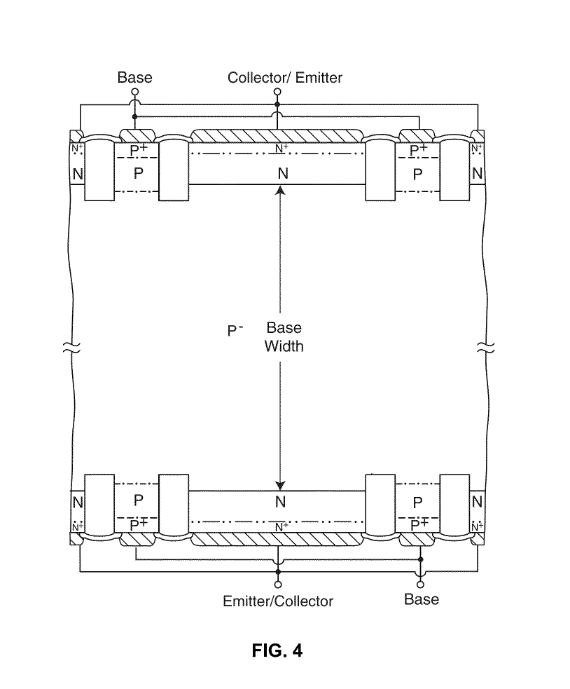

FIG. 1 schematically shows an example of an improved B-TRAN, in which series resistance between each base contact location 143 and the voltage-withstand region (substrate) 100 is reduced as disclosed in the present application. Specifically, a p-type resistance-lowering region 134 is added below the p+ base contact doping 132 in each base contact location 143. This structure uses trenches 120 that have a silicon dioxide liner filled with polycrystalline silicon (polysilicon) 122 that is subsequently doped to make the polysilicon conductive. The trenches provide lateral separation between the p-type base regions and the n-type emitter/collector regions at the wafer surfaces.

The present application describes a fabrication sequence that reduces the value of the parasitic base resistance in a B-TRAN. The origin of the unwanted parasitic base resistance can be understood by referring to FIG. 2, which is the cross section of the top half of a B-TRAN fabricated using a lightly doped p-type silicon wafer 100 as the starting substrate.

The resistance between the metal base contact at the device surface and the base region below the center of the emitter is known as the base resistance, “r_{b}” and consists of two segments:

1. The intrinsic base resistance “r_{b1}” which is the resistance of the base below the emitter; and

2. The extrinsic base resistance “r_{b2}” which is the resistance of the base from the outer edge of the emitter to the metal contact to the base.

Both of these segments contribute to the voltage drop when current flows through them. However, it is difficult to reduce the intrinsic base resistance, r_{b1}, since the resistivity of the p-type base in this region is high so that the reverse biased base-to-collector junction will sustain the required voltage. However, the extrinsic base resistance, r_{b2}, can be reduced without affecting the breakdown voltage as long as it is done properly. Specifically, both a P+ contact region and a deeper p-type region can be formed at separate times in the fabrication, with each of these two regions reducing the extrinsic base resistance rb2. Such a structure is shown in FIG. 1. Concerning each of these two regions:

1. The dopant that forms the P+ base contact region may be introduced before the single drive-in step that is used to diffuse all dopant species prior to the contact mask on side 2. If so, a slow diffusing p-type atom such as indium should be chosen. Alternately, the P+ contact region may be introduced through the contact mask over regions where a low P+ contact region is desired. Then boron or indium may be used. However, in the B-TRAN process flow, the P+ contact implant on side 1 cannot be fully activated since the wafers are restricted to remain at or below 450 C to prevent an unwanted interaction between the metal and the silicon in the contact opening.

2. The dopant that forms the p-type resistance-lowering region must be introduced before the single drive-in step. However, this drive-in step also diffuses the n-type emitter/collector region to its final profile and depth. If the implanted dose of the p-type dopant (typically boron) is too low, the p-type diffused region does not extend deeply into the p-type substrate, and the extrinsic base resistance is not decreased as much as is possible. If the implanted dose of the p-type dopant is too high, the resulting dopant profile will extend below the bottom of the trench, where it can reduce the base-to-collector reverse breakdown voltage. There is an implant dose for a given trench configuration (depth, sidewall oxide thickness, corner radius, etc.) that will provide a reduction in the extrinsic base resistance without reducing the breakdown voltage, as long as the n-type region is approximately the same depth as the trenches. (Note: If the emitter/collector-to-base region is considerably shallower that the trenches, the base width will be wider than needed, reducing B-TRAN performance.) This implant dose may be found, starting with a given trench depth, p-dopant concentration, and emitter/collector dopant profile using either simulation techniques, or by varying the p-type implant dose and measuring the base-to emitter/collector breakdown voltage. The goal is to determine the implant dose that provides a low extrinsic base resistance without (or at most, only slightly) reducing the collector-to-base breakdown voltage.

To implement this, the additional p-type boron implant preferably occurs on both surfaces prior to the combined drive-in step. The details of this implant step:
a. Dose: 1×10¹⁵
b. Energy: 80 kev
c. Species: Boron 11
d. Profile: P++ contact implant and p-type implant—.

2. P++ contact implant occurs after the combined drive-in step. E.g.:
a. Dose: 2×10¹⁵
b. Energy: 80 kev (B11) or 30 kev (BF2)
c. Species: Boron 11 or BF2
d. Side 1: Low temperature activation, since metal already on Side 2.
e. Side 2: High temperature activation.

In one example, the “drive-in” step that diffuses the dopants to their final junction depth is: a. 25 min dry O2 at 1150 C, followed by b. 120 min N2 at 1150 C.

The P++ activation on Side 2 prior to metallization takes place during the BPSG flow step: e.g. 30 min N2 at 900 C.

The P++ activation on side 1 after metallization of Side 2 is effected by the metal anneal stop: e.g. 60 minutes in forming gas (N2/H2) at 450 C.

To form the n and n+ regions, both phosphorus and arsenic are implanted: e.g. a. Phosphorus: 5×10¹⁵ at 80 kev, and b. Arsenic: 3×10¹⁵ at 50 kev.

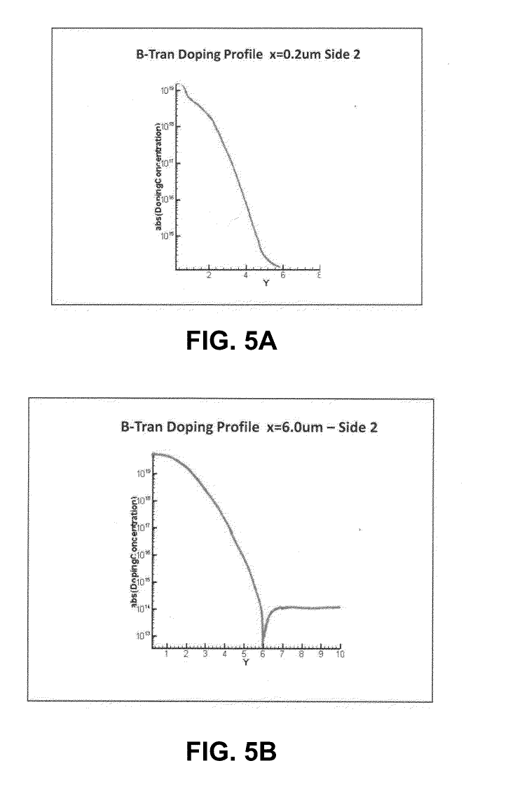

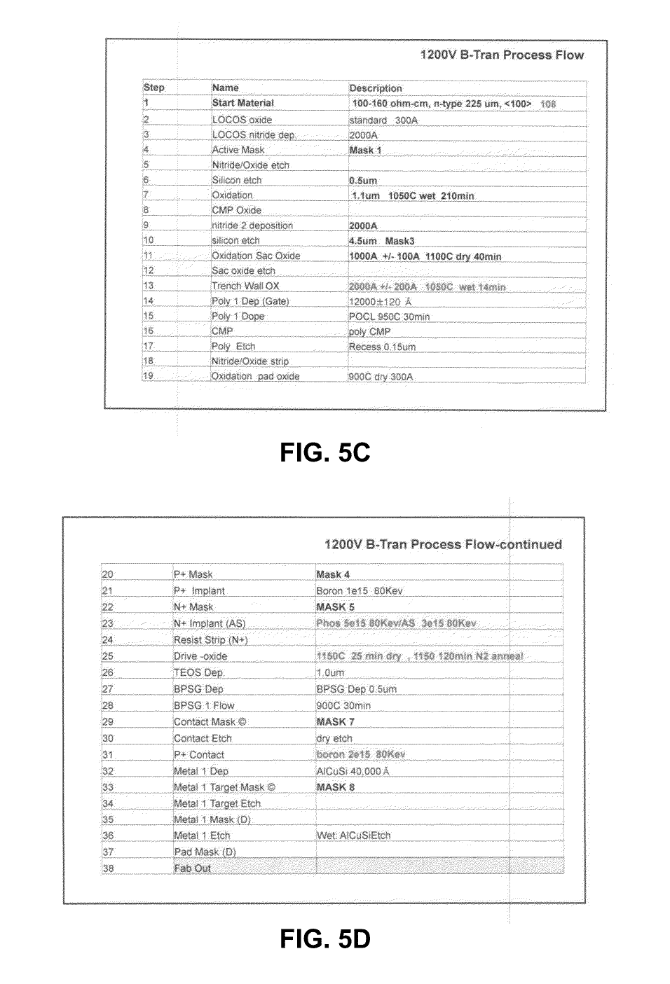

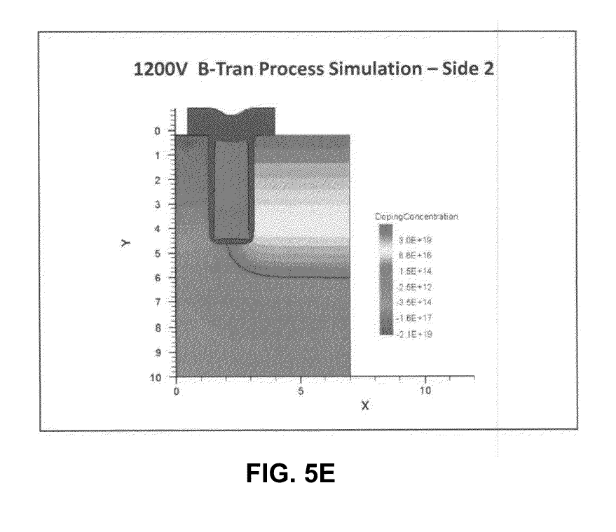

FIGS. 5A-5E show simulation results for various embodiments of the disclosed inventions. Note particularly that, while the thermal history of the dopants on the first and second side is slightly different, only a small difference in junction depth results from this.

### Advantages

The disclosed innovations, in various embodiments, provide one or more of at least the following advantages. However, not all of these advantages result from every one of the innovations disclosed, and this list of advantages does not limit the various claimed inventions.
Improved efficiency in power conversion systems.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A B-TRAN having a resistance-reducing doping component under base contact locations on both front and back surfaces.

2. A method of operating a B-TRAN in transistor mode, comprising: flowing base current through a base contact region which on the opposite side of a generally planar die from the emitter/collector region which is biased to operate as an emitter; the base current being flowed not only through a shallow base contact region, but also through a deeper and more lightly dope resistance reducing region which is interposed between the base contact region and the bulk of the semiconductor die.

3-6. (canceled)
